(19) United States
(12) Patent Application Publication
(10) Pub. No.: US 2026/0090043 A1
(43) Pub. Date: Mar. 26, 2026

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Shingo SATO, Kanazawa Ishikawa (JP)

(21) Appl. No.: 19/042,567

(22) Filed: Jan. 31, 2025

(30) Foreign Application Priority Data
Sep. 20, 2024 (JP) 2024-164303

(51) Int. Cl. H10D 62/10; H10D 30/66

(52) U.S. Cl. CPC H10D 62/126; H10D 30/66

(57) ABSTRACT

According to one embodiment, a semiconductor device includes a first electrode, a first semiconductor region of a first conductivity type, second semiconductor regions of a second conductivity type, a third semiconductor region of the second conductivity type, a fourth semiconductor region of the first conductivity type, a gate electrode, fifth semiconductor regions of the second conductivity type, sixth semiconductor regions of the second conductivity type, and a second electrode. The fifth semiconductor regions are arranged with the second semiconductor regions in a second direction. A distance between two of the fifth semiconductor regions adjacent to each other is longer than a distance between two of the second semiconductor regions adjacent to each other. The sixth semiconductor regions are provided in the second portion. The sixth semiconductor regions are arranged with the second semiconductor regions in a third direction.

### CROSS-REFERENCE TO RELATED APPLICATIONS

This application is based upon and claims the benefit of priority from Japanese Patent Application No. 2024-164303, filed on Sep. 20, 2024; the entire contents of which are incorporated herein by reference.

### FIELD

Embodiments of the present invention generally relate to a semiconductor device.

### BACKGROUND

Semiconductor devices such as metal oxide semiconductor field effect transistors (MOSFETs) are used for applications such as power conversion. There is a need for technology that can reduce the size of semiconductor devices.

### BRIEF DESCRIPTION OF THE DRAWINGS

FIG. 1 is a plan view illustrating a semiconductor device according to the embodiment;

FIG. 2 is a perspective cross-sectional view including a II-II cross-section of FIG. 1;

FIG. 3 is an enlarged plan view of a portion III of FIG. 1;

FIG. 4 is an enlarged plan view of a portion III of FIG. 1;

FIG. 5 is a V-V cross-sectional view of FIGS. 3 and 4;

FIG. 6 is a VI-VI cross-sectional view of FIGS. 3 and 4;

FIG. 7A is an enlarged cross-sectional view of a portion A in FIG. 4, and FIG. 7B is an enlarged cross-sectional view of a portion B in FIG. 4;

FIG. 8 is a cross-sectional view illustrating a manufacturing process of the semiconductor device according to the embodiment;

FIG. 9 is a plan view illustrating the manufacturing process of the semiconductor device according to the embodiment;

FIG. 10 is a plan view illustrating the manufacturing process of the semiconductor device according to the embodiment;

FIG. 11 is a plan view illustrating the manufacturing process of the semiconductor device according to the embodiment;

FIGS. 12A and 12B are cross-sectional views illustrating the manufacturing process of the semiconductor device according to the embodiment;

FIG. 13 is a plan view illustrating a portion of a semiconductor device according to a reference example;

FIG. 14 is a plan view illustrating a portion of a semiconductor device according to a first modification of the embodiment; and

FIG. 15 is a plan view illustrating a portion of a semiconductor device according to a second modification of the embodiment.

### DETAILED DESCRIPTION

According to one embodiment, a semiconductor device includes a first electrode, a first semiconductor region of a first conductivity type, a plurality of second semiconductor regions of a second conductivity type, a third semiconductor region of the second conductivity type, a fourth semiconductor region of the first conductivity type, a gate electrode, a plurality of fifth semiconductor regions of the second conductivity type, a plurality of sixth semiconductor regions of the second conductivity type, and a second electrode. The first semiconductor region is provided on the first electrode. The first semiconductor region includes a first portion and a second portion. The second portion is provided around the first portion in a first plane that is perpendicular to a first direction from the first electrode toward the first semiconductor region. The plurality of second semiconductor regions are provided in the first portion. The plurality of second semiconductor regions are separated from each other in a second direction and a third direction. The second direction is perpendicular to the first direction. The third direction is perpendicular to the first direction and the second direction. The third semiconductor region is provided on a portion of the plurality of second semiconductor regions arranged in the third direction. An impurity concentration of the second conductivity type in the third semiconductor region is greater than impurity concentrations of the second conductivity type in the portion of the plurality of second semiconductor regions. The fourth semiconductor region is provided on the third semiconductor region. The gate electrode faces the third semiconductor region via a gate insulating layer. The plurality of fifth semiconductor regions are provided in the second portion. The plurality of fifth semiconductor regions are arranged with the plurality of second semiconductor regions in the second direction. The plurality of fifth semiconductor regions are separated from each other in the second direction. A distance between two of the plurality of fifth semiconductor regions adjacent to each other is longer than a distance between two of the plurality of second semiconductor regions adjacent to each other. The plurality of sixth semiconductor regions are provided in the second portion. The plurality of sixth semiconductor regions are arranged with the plurality of second semiconductor regions in the third direction. The plurality of sixth semiconductor regions are separated from each other in the second direction and the third direction. The second electrode is provided on the third semiconductor region and the fourth semiconductor region.

Embodiments of the invention will now be described with reference to the drawings. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated. In the drawings and the specification of the application, components similar to those described thereinabove are marked with like reference numerals, and a detailed description is omitted as appropriate.

In the following descriptions and drawings, notations of n⁺, n, n⁻ and p⁺, p, p⁻ represent relative levels of impurity concentrations in conductivity types. That is, the notation with “+” shows a relatively higher impurity concentration than an impurity concentration for the notation without any of “+” and “−”. The notation with “−” shows a relatively lower impurity concentration than the impurity concentration for the notation without any of them. These notations represent relative levels of net impurity concentrations after the mutual compensation of these impurities when respective regions include both of a p-type impurity and an n-type impurity.

The embodiments described below may be implemented by reversing the p-type and the n-type of the semiconductor regions.

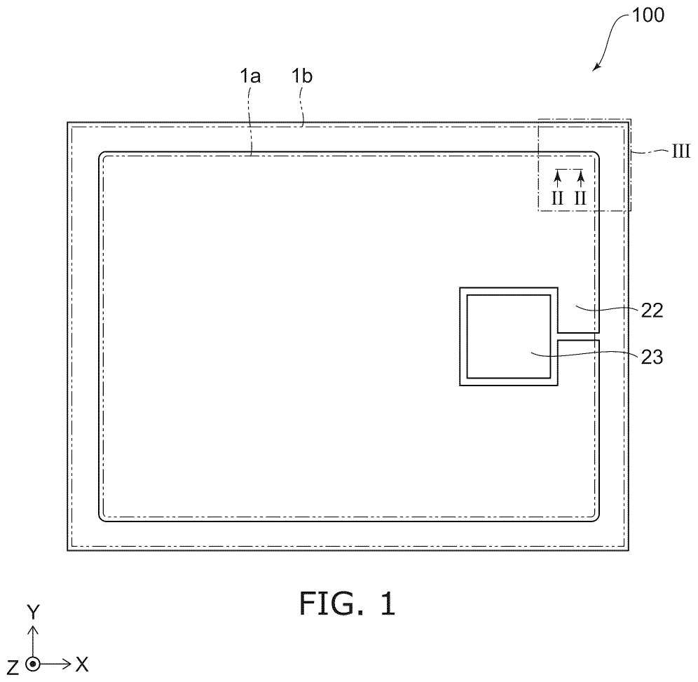

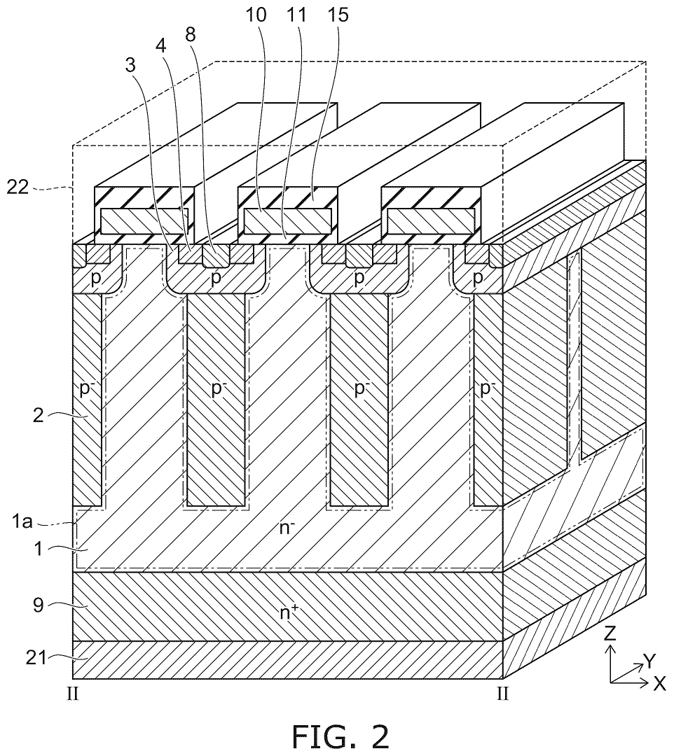

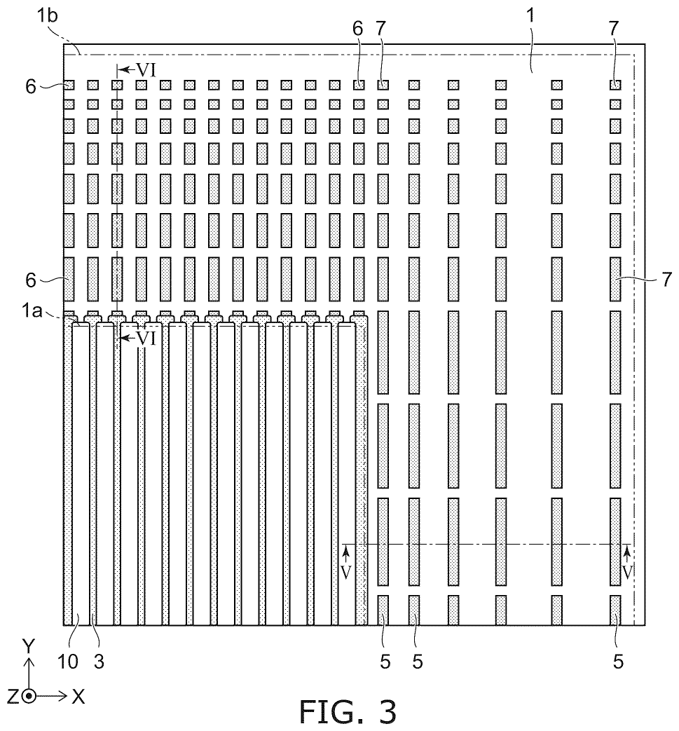

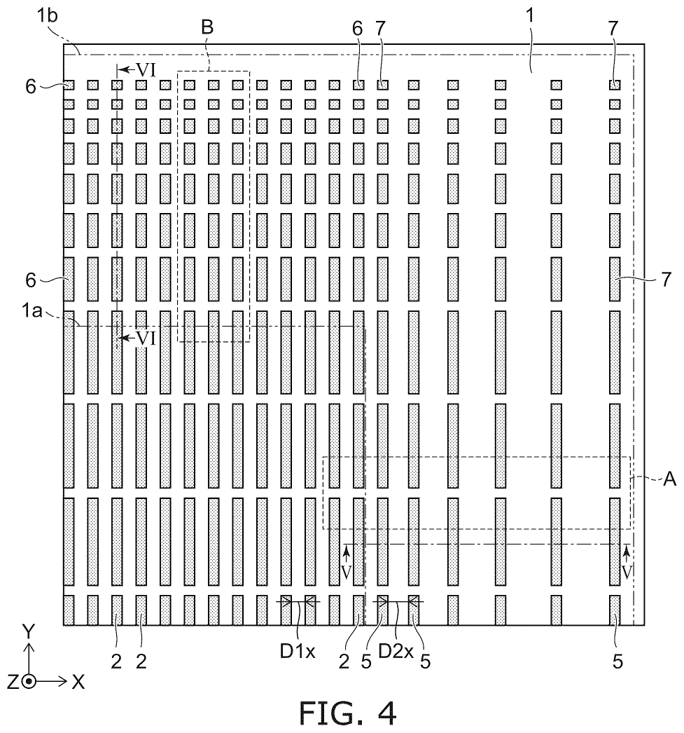

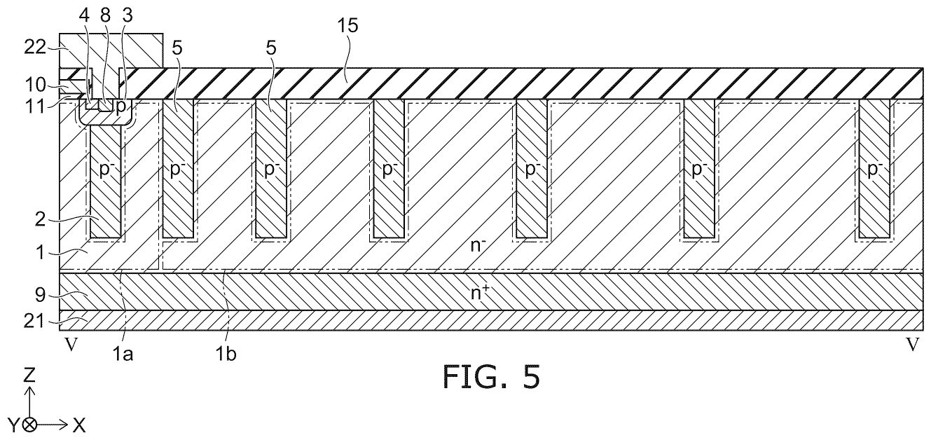

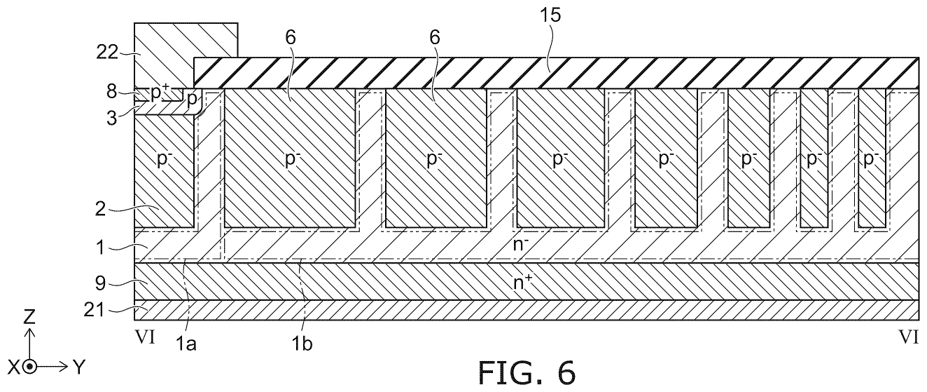

FIG. 1 is a plan view illustrating a semiconductor device according to the embodiment. FIG. 2 is a perspective cross-sectional view including a II-II cross-section of FIG. 1. FIGS. 3 and 4 are enlarged plan views of a portion III of FIG. 1. FIG. 5 is a V-V cross-sectional view of FIGS. 3 and 4. FIG. 6 is a VI-VI cross-sectional view of FIGS. 3 and 4.

The semiconductor device 100 according to the embodiment is a MOSFET. As shown in FIGS. 1 to 6, the semiconductor device 100 includes an n-type (a first conductivity type) drift region 1 (a first semiconductor region), a p-type (a second conductivity type) pillar region 2 (a second semiconductor region), a p-type base region 3 (a third semiconductor region), an n⁺-type source region 4 (a fourth semiconductor region), p⁻-type pillar region 5 (a fifth semiconductor region), p⁻-type pillar region 6 (a sixth semiconductor region), p⁻-type pillar region 7 (a seventh semiconductor region), an n⁺-type contact region 8, an n⁺-type drain region 9, a gate electrode 10, a gate insulating layer 11, an insulating layer 15, a drain electrode 21 (a first electrode), a source electrode 22 (a second electrode), and a gate pad 23. In FIG. 3, the n⁺-type source region 4, the p⁺-type contact region 8, the insulating layer 15, and the source electrode 22 are omitted. In FIG. 4, the p-type base region 3, the n⁺-type source region 4, the p⁺-type contact region 8, the gate insulating layer 11, the insulating layer 15, and the source electrode 22 are omitted.

An XYZ orthogonal coordinate system is used in the description of the embodiments. A direction from the drain electrode 21 toward the n⁻-type drift region 1 is taken as a Z-direction (a first direction); and two mutually-orthogonal directions perpendicular to the Z-direction are taken as an X-direction (a second direction) and a Y-direction (a third direction). In the description, the direction from the drain electrode 21 toward the n⁻-type drift region 1 is called “up/upward/above”, and the opposite direction is called “down/downward/below”. These directions are based on the relative positional relationship between the drain electrode 21 and the n⁻-type drift region 1, and are independent of the direction of gravity.

As shown in FIG. 1, the source electrode 22 and the gate pad 23 are provided on the upper surface of the semiconductor device 100. The source electrode 22 and the gate pad 23 are separated from each other and electrically isolated.

As shown in FIG. 2, the drain electrode 21 is provided on the lower surface of the semiconductor device 100. The n⁺-type drain region 9 is provided on the drain electrode 21 and is electrically connected to the drain electrode 21. The n⁻-type drift region 1 is provided on the n⁺-type drain region 9. The n⁻-type drift region 1 is electrically connected to the drain electrode 21 via the n⁺-type drain region 9. The n-type impurity concentration in the n⁻-type drift region 1 is lower than the n-type impurity concentration in the n⁺-type drain region 9.

The n⁻-type drift region 1 includes a first portion 1a and a second portion 1b as shown in FIGS. 1 to 6. The second portion 1b is located around the first portion 1a in the X-Y plane (a first plane). The first portion 1a is located in a cell region. The cell region is the region through which a current mainly flows when the semiconductor device 100 operates. The second portion 1b is located in a termination region. The termination region is the region where a depletion layer spreads toward the outer periphery of the semiconductor device 100 when the semiconductor device 100 withstands a voltage.

As shown in FIG. 2, the p⁻-type pillar region 2 is provided in the first portion 1a. Multiple p⁻-type pillar regions 2 are provided in the X-direction and the Y-direction. The multiple p⁻-type pillar regions 2 are separated from each other. A part of the first portion 1a and the p⁻-type pillar region 2 are alternately arranged in the X-direction and the Y-direction. The length of the p⁻-type pillar region 2 in the Y-direction is longer than the length of the p⁻-type pillar region 2 in the X-direction. The length of the p⁻-type pillar region 2 in the Y-direction is longer than the distance between adjacent p⁻-type pillar regions 2 in the Y-direction.

The p-type base region 3 is provided on multiple p⁻-type pillar regions 2 arranged in the Y-direction. The n⁺-type source region 4 and the p⁺-type contact region 8 are provided on the p-type base region 3. The gate electrode 10 is provided, with a gate insulating layer 11 interposed, on a portion of the n⁻type drift region 1, the p-type base region 3, and the n⁺-type source region 4.

The source electrode 22 is located on the p-type base region 3, the n⁺-type source region 4, and the p⁺-type contact region 8, and is electrically connected to the p-type base region 3, the n⁺-type source region 4, and the p⁺-type contact region 8. The gate electrode 10 and the source electrode 22 are electrically isolated from each other by the insulating layer 15.

As shown in FIGS. 3 to 5, the p⁻-type pillar region 5 is provided in the second portion 1b. The p⁻-type pillar region 5 is arranged with the p⁻-type pillar region 2 in the X-direction. Multiple p⁻-type pillar regions 5 are provided in the X-direction and the Y-direction. The multiple p⁻-type pillar regions 5 are separated from each other. A part of the second portion 1b and the p⁻-type pillar region 5 are alternately arranged in the X-direction and the Y-direction. The length of the p⁻-type pillar region 5 in the Y-direction is longer than the length of the p⁻-type pillar region 5 in the X-direction. The length of the p⁻-type pillar region 5 in the Y-direction is longer than the distance between adjacent p⁻-type pillar regions 5 in the Y-direction. As shown in FIG. 4, the distance D2x between adjacent p⁻-type pillar regions 5 in the X-direction is longer than the distance D1x between adjacent p⁻-type pillar regions 2 in the X-direction.

As shown in FIGS. 3, 4, and 6, the p⁻-type pillar region 6 is provided in the second portion 1b. The p⁻-type pillar region 6 is arranged with the p⁻-type pillar region 2 in the Y-direction. Multiple p⁻-type pillar regions 6 are provided in the X-direction and the Y-direction, and the multiple p⁻-type pillar regions 6 are separated from each other. A part of the second portion 1b and the p⁻-type pillar region 6 are alternately arranged in the X-direction and the Y-direction.

As shown in FIGS. 3 and 4, the p⁻-type pillar region 7 is provided in the second portion 1b. The p⁻-type pillar region 7 is arranged with the p⁻-type pillar region 5 in the Y-direction, and is arranged with the p⁻-type pillar region 6 in the X-direction. Multiple p⁻-type pillar regions 7 are provided in the X-direction and the Y-direction, and the multiple p⁻-type pillar regions 7 are separated from each other. A part of the second portion 1b and the p⁻-type pillar region 7 are alternately arranged in the X-direction and the Y-direction.

For example, the positions in the Z-direction of the lower ends of the p⁻-type pillar region 2, the p⁻-type pillar region 5, the p⁻-type pillar region 6, and the p⁻-type pillar region 7 are the same as each other. In other words, the distance in the Z-direction between the drain electrode 21 and the p⁻-type pillar region 2, the distance in the Z-direction between the drain electrode 21 and the p⁻-type pillar region 5, the distance in the Z-direction between the drain electrode 21 and the p⁻-type pillar region 6, and the distance in the Z-direction between the drain electrode 21 and the p⁻-type pillar region 7 are the same as each other.

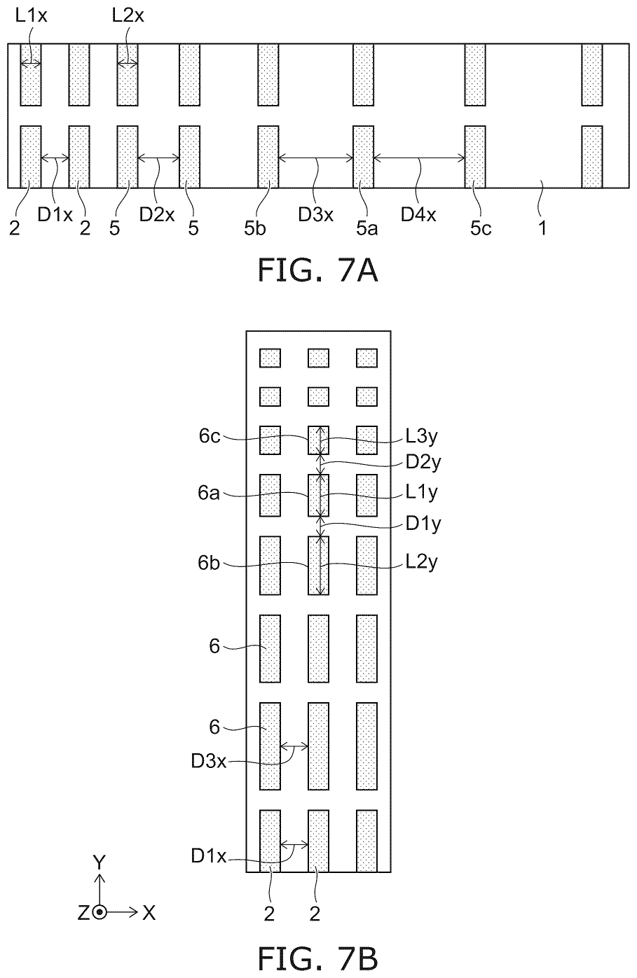

FIG. 7A is an enlarged cross-sectional view of a portion A in FIG. 4. FIG. 7B is an enlarged cross-sectional view of a portion B in FIG. 4. As described above, as long as the interval in the X-direction between the p⁻-type pillar regions 5 is longer than the interval in the X-direction between the p⁻-type pillar regions 2, and multiple p⁻-type pillar regions 6 are provided in the X-direction and the Y-direction, the specific configuration of the semiconductor device 100 can be modified as appropriate. Here, with reference to FIGS. 7A and 7B, a specific example related to the p⁻-type pillar regions 5 and the p⁻-type pillar regions 6 will be described.

The distance in the X-direction between adjacent p⁻-type pillar regions 5 is preferably longer toward the outer periphery of the semiconductor device 100. For example, as shown in FIG. 7A, the multiple p⁻-type pillar regions 5 include p⁻-type pillar regions 5a to 5c adjacent to each other in the X-direction. The p⁻-type pillar region 5a is one of the multiple p⁻-type pillar regions 5. The p⁻-type pillar region 5b is another one of the multiple p⁻-type pillar regions 5. The p⁻-type pillar region 5c is yet another one of the multiple p⁻-type pillar regions 5. The p⁻-type pillar region 5a is positioned between the p⁻-type pillar region 5b and the p⁻-type pillar region 5c in the X-direction. The p⁻-type pillar region 5b is positioned between the p⁻-type pillar region 2 and the p⁻-type pillar region 5a in the X-direction. The distance D4x in the X-direction between the p⁻-type pillar region 5a and the p⁻-type pillar region 5c is longer than the distance D3x in the X-direction between the p⁻-type pillar region 5a and the p⁻-type pillar region 5b.

The length of each p⁻-type pillar region 6 in the Y-direction is preferably shorter toward the outer periphery of the semiconductor device 100. For example, as shown in FIG. 7B, the multiple p⁻-type pillar regions 6 include p⁻-type pillar regions 6a to 6c adjacent to each other in the Y-direction. The p⁻-type pillar region 6a is one of the multiple p⁻-type pillar regions 6. The p⁻-type pillar region 6b is another one of the multiple p⁻-type pillar regions 6. The p⁻-type pillar region 6c is yet another one of the multiple p⁻-type pillar regions 6. The p⁻-type pillar region 6a is positioned between the p⁻-type pillar region 6b and the p⁻-type pillar region 6c in the Y-direction. The p⁻-type pillar region 6b is positioned between the p⁻-type pillar region 2 and the p⁻-type pillar region 6a in the Y-direction. The length L1y of the p⁻-type pillar region 6a in the Y-direction is shorter than the length L2y of the p⁻-type pillar region 6b in the Y-direction, and longer than the length L3y of the p⁻-type pillar region 6c in the Y-direction.

The distance between adjacent p⁻-type pillar regions 6 in the Y-direction may be uniform or may be different from each other. Preferably, the distances between p⁻-type pillar regions 6 are the same. For example, the distance D1y in the Y-direction between the p⁻-type pillar region 6a and the p⁻-type pillar region 6b is the same as the distance D2y in the Y-direction between the p⁻-type pillar region 6a and the p⁻-type pillar region 6c. The distance D3x between adjacent p⁻-type pillar regions 6 in the X-direction is preferably the same as the distance D1x between adjacent p⁻-type pillar regions 2 in the X-direction.

The arrangement in the X-direction of the multiple p⁻-type pillar regions 7 is substantially the same as the arrangement in the X-direction of the multiple p⁻-type pillar regions 5. In other words, each p⁻-type pillar region 7 is arranged with any p⁻-type pillar region 5 in the Y-direction. The distance between adjacent p⁻-type pillar regions 7 in the X-direction is longer toward the outer periphery of the semiconductor device 100.

The arrangement in the Y-direction of the multiple p⁻-type pillar regions 7 is substantially the same as the arrangement in the Y-direction of the multiple p⁻-type pillar regions 6. In other words, each p⁻-type pillar region 7 is arranged with any p⁻-type pillar region 6 in the X-direction. The length in the Y-direction of each p⁻-type pillar region 7 is shorter toward the outer periphery of the semiconductor device 100.

For example, the length of the p⁻-type pillar region 7 in the X-direction is the same as the length of the p⁻-type pillar region 5 in the X-direction. The distance between adjacent p⁻-type pillar regions 7 in the X-direction becomes longer toward the outer periphery of the semiconductor device 100.

One of the multiple p⁻-type pillar regions 7 is adjacent to another one of the multiple p⁻-type pillar regions 7 and yet another one of the multiple p⁻-type pillar regions 7 in the X-direction, and positioned therebetween. The other one of the multiple p⁻-type pillar regions 7 is positioned between one of the multiple p⁻-type pillar regions 6 and the one of the multiple p⁻-type pillar regions 7. The distance between the one of the multiple p⁻-type pillar regions 7 and the yet other one of the multiple p⁻-type pillar regions 7 is longer than the distance between the one of the multiple p⁻-type pillar regions 7 and the other one of the multiple p⁻-type pillar regions 7.

The length of the one of the multiple p⁻-type pillar regions 7 in the X-direction, the length of the other one of the multiple p⁻-type pillar regions 7 in the X-direction, and the length of the yet other one of the multiple p⁻-type pillar regions 7 in the X-direction are the same.

The length of each p⁻-type pillar region 7 in the Y-direction becomes shorter toward the outer periphery of the semiconductor device 100.

One of the multiple p⁻-type pillar regions 7 is positioned between another one of the multiple p⁻-type pillar regions 7 and yet another one of the multiple p⁻-type pillar regions 7 in the Y-direction. The other one of the multiple p⁻-type pillar regions 7 is positioned in the Y-direction between one of the multiple p⁻-type pillar regions 5 and the one of the multiple p⁻-type pillar regions 7. The length of the one of the multiple p⁻-type pillar regions 7 in the Y-direction is shorter than the length of the other one of the multiple p⁻-type pillar regions 7 in the Y-direction and longer than the length of the yet other one of the multiple p⁻-type pillar regions 7 in the Y-direction.

For example, the one of the multiple p⁻-type pillar regions 7 is adjacent to the other one of the multiple p⁻-type pillar regions 7 and the yet other one of the multiple p⁻-type pillar regions 7 in the Y-direction. The distance between the one of the multiple p⁻-type pillar regions 7 and the other one of the multiple p⁻-type pillar regions 7 is the same as the distance between the one of the multiple p⁻-type pillar regions 7 and the yet other one of the multiple p⁻-type pillar regions 7.

The semiconductor device 100 has a super-junction structure in which parts of the n⁻-type drift region 1 and the p⁻-type pillar regions are alternately arranged along the X-Y plane. Here, a portion of the n⁻-type drift region 1 adjacent to the p⁻-type pillar region is also referred to as “an n⁻-type pillar region”. In the super-junction structure, it is desirable that the difference between the amount of p-type impurities contained in one p⁻-type pillar region and the amount of n-type impurities contained in the adjacent n⁻-type pillar region is small.

An example of the material of each component will now be described. The n⁻-type drift region 1, the p⁻-type pillar region 2, the p-type base region 3, the n⁺-type source region 4, the p⁻-type pillar region 5, the p⁻-type pillar region 6, the p⁻-type pillar region 7, the p⁺-type contact region 8, and the n⁺-type drain region 9 include silicon, silicon carbide, gallium nitride, or gallium arsenide as a semiconductor material. When silicon is used as the semiconductor material, arsenic, phosphorus, or antimony can be used as an n-type impurity. Boron can be used as a p-type impurity. The gate electrode 10 includes a conductive material such as polysilicon. The gate insulating layer 11 and the insulating layer 15 include an insulating material such as silicon oxide, silicon nitride, or silicon oxynitride. The drain electrode 21, the source electrode 22, and the gate pad 23 include a metal such as titanium, aluminum, or copper.

The operation of the semiconductor device 100 will now be described. In a state where a positive voltage with respect to the source electrode 22 is applied to the drain electrode 21, a voltage not less than a threshold is applied to the gate electrode 10. As a result, a channel (an inversion layer) is formed in the p⁻-type base region 3, and the semiconductor device 100 is turned on. Electrons flow from the source electrode 22 to the n⁻-type drift region 1 through the channel. Thereafter, when the voltage applied to the gate electrode 10 becomes lower than the threshold, the channel in the p⁻-type base region 3 disappears; and the semiconductor device 100 is turned off.

When the semiconductor device 100 switches from the on-state to the off-state while a positive voltage is applied to the drain electrode 21, a depletion layer spreads from the p-n junction surfaces between the n⁻-type drift region 1 and each of the p⁻-type pillar region 2, the p⁻-type pillar region 5, the p⁻-type pillar region 6, and the p⁻-type pillar region 7. Due to the spread of the depletion layer, the breakdown voltage of the semiconductor device 100 can be improved. Alternatively, while maintaining the breakdown voltage of the semiconductor device 100, the n-type impurity concentration in the n⁻-type drift region 1 can be increased, thereby reducing the on-resistance of the semiconductor device 100.

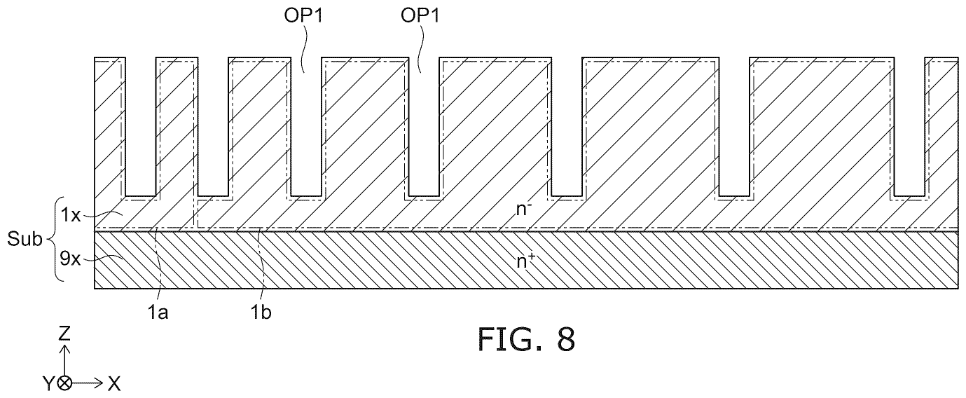

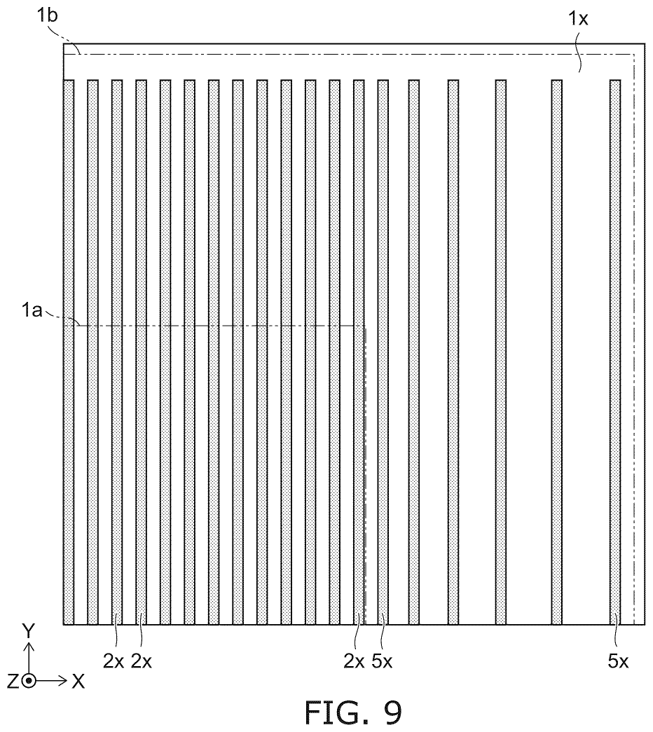

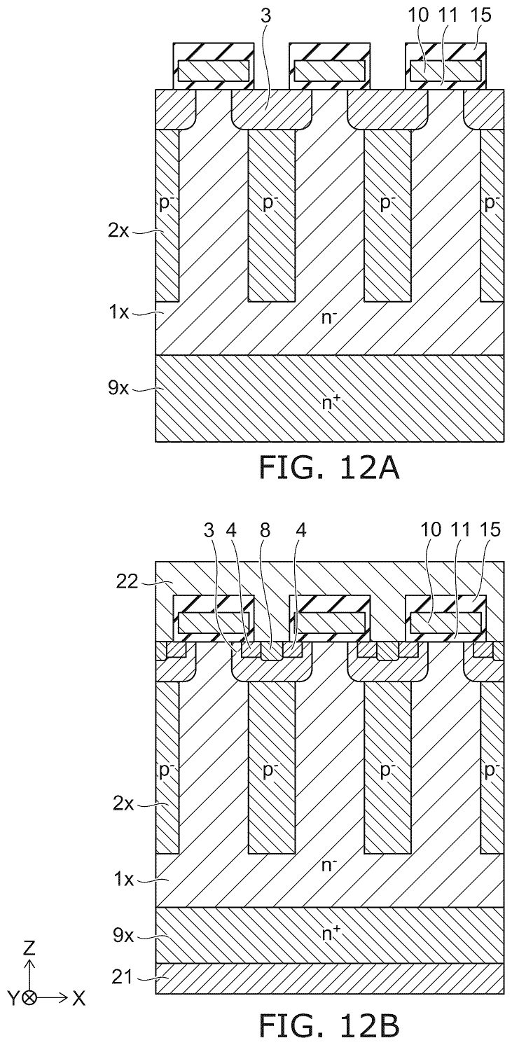

FIGS. 8, 12A, and 12B are cross-sectional views illustrating a manufacturing process of the semiconductor device according to the embodiment. FIGS. 9 to 11 are plan views illustrating the manufacturing process of the semiconductor device according to the embodiment. FIG. 8 illustrates the manufacturing process at the position of the V-V cross-section shown in FIGS. 3 and 4. FIGS. 12A and 12B illustrate the manufacturing process at the position of the II-II cross-section shown in FIG. 1.

First, a semiconductor substrate Sub including an n⁺-type semiconductor layer 9x and an n⁻-type semiconductor layer 1x is prepared. Multiple openings OP1 are formed on the upper surface of the n⁻-type semiconductor layer 1x by reactive ion etching (RIE), as shown in FIG. 8. The multiple openings OP1 are arranged in the X-direction, and each opening OP1 extends in the Y-direction.

The n⁻-type semiconductor layer 1x includes the first portion 1a and the second portion 1b. Some of the multiple openings OP1 pass through the first portion 1a. The others of the multiple openings OP1 do not pass through the first portion 1a and are located only in the second portion 1b. The distance between the openings OP1 formed in the second portion 1b is longer than the distance between the openings OP1 passing through the first portion 1a. The distance between the openings OP1 formed in the second portion 1b becomes longer toward the region that will be processed as the outer periphery of the semiconductor device 100. The width (length in the X-direction) of each opening OP1 is the same as each other.

A semiconductor layer containing p-type impurities is epitaxially grown on the n⁻-type semiconductor layer 1x. The openings OP1 are filled with the semiconductor layer. The upper surface of the semiconductor layer is flattened by chemical mechanical polishing (CMP). As a result, as shown in FIG. 9, p⁻-type semiconductor layers 2x are formed inside the openings OP1 passing through the first portion 1a. P-type semiconductor layers 5x are formed inside the openings OP1 formed in the second portion 1b.

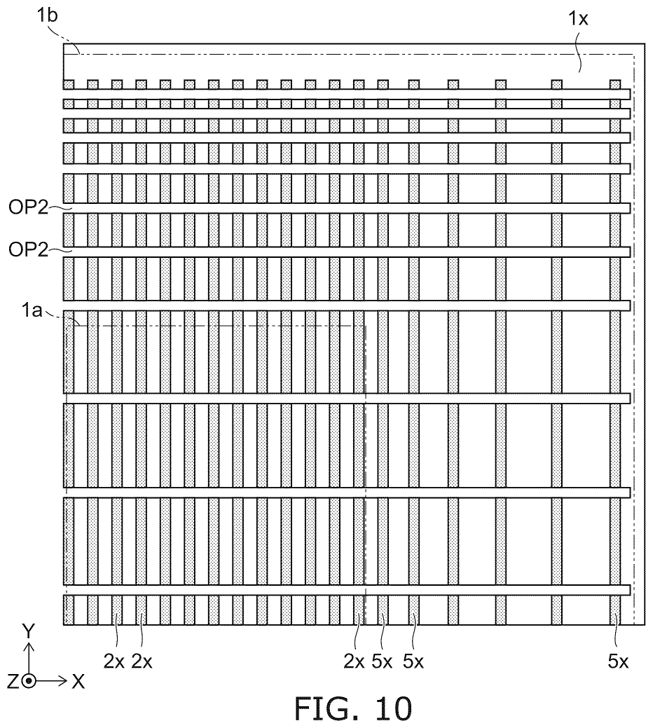

A portion of the n⁻-type semiconductor layer 1x, a portion of the p⁻-type semiconductor layer 2x, and a portion of the p⁻-type semiconductor layer 5x are removed by RIE. As a result, multiple openings OP2 are formed, as shown in FIG. 10. The multiple openings OP2 are arranged in the Y-direction, and each opening OP2 extends in the X-direction. The openings OP2 are formed in the first portion 1a and the second portion 1b. In the second portion 1b, the distance in the Y-direction between the openings OP2 becomes shorter toward the region that will be processed as the outer periphery of the semiconductor device 100. The width (length in the Y-direction) of each opening OP2 is the same as each other.

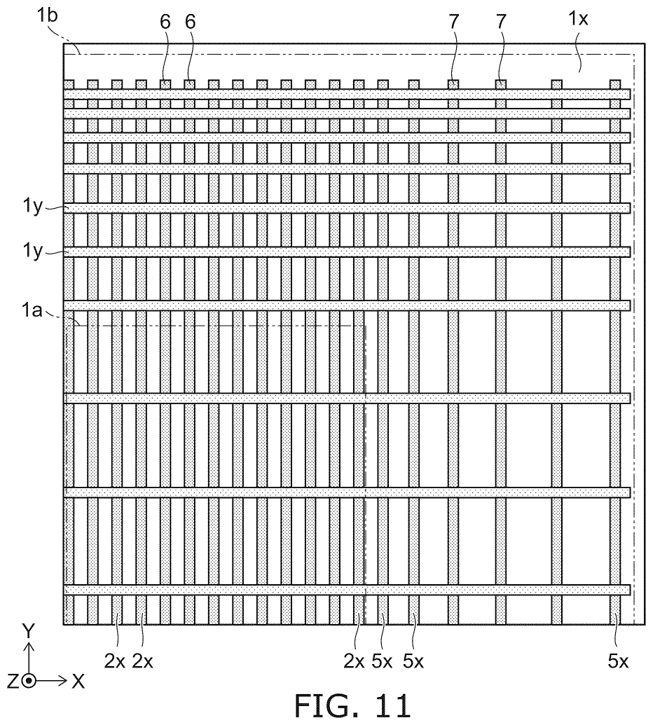

A semiconductor layer containing n-type impurities is epitaxially grown to fill the openings OP2. The upper surface of the semiconductor layer is flattened by CMP. As a result, an n⁻-type semiconductor layer 1y is formed inside each openings OP2, as shown in FIG. 11. For example, the n-type impurity concentration in the n⁻-type semiconductor layer 1y is the same as the n-type impurity concentration in the n⁻-type semiconductor layer 1x. The n-type impurity concentration in the n⁻-type semiconductor layer 1y may be different from the n-type impurity concentration in the n⁻-type semiconductor layer 1x. The p⁻-type semiconductor layer 2x and the p⁻-type semiconductor layer 5x are divided into multiple sections in the Y-direction by the n⁻-type semiconductor layers 1y.

In the state shown in FIG. 11, parts of the divided p⁻-type semiconductor layers 2x are located in the first portion 1a. These parts of the divided p⁻-type semiconductor layers 2x correspond to the p⁻-type pillar regions 2. Other parts of the divided p⁻-type semiconductor layers 2x are located in the second portion 1b. The other parts of the p⁻-type semiconductor layers 2x correspond to the p⁻-type pillar regions 6. In addition, the p⁻-type semiconductor layers 5x are divided by the n⁻-type semiconductor layers 1y. The divided p⁻-type semiconductor layers 5x correspond to the p⁻-type pillar regions 5 and the p⁻-type pillar regions 7.

P-type impurities are ion-implanted into the upper portion of the multiple p⁻-type pillar regions 2 arranged in the Y-direction to form the p-type base region 3. The gate insulating layer 11 is formed on the upper surface of the n⁻-type semiconductor layer 1x and the upper surface of the p-type base region 3 by thermal oxidation. A polysilicon layer is formed on the gate insulating layer 11 by chemical vapor deposition (CVD). The polysilicon layer is patterned to form the gate electrode 10. The insulating layer 15 covering the gate electrode 10 is formed by CVD. As shown in FIG. 12A, a portion of the insulating layer 15 and a portion of the gate insulating layer 11 are removed by RIE to expose the upper surface of the p-type base region 3.

N-type impurities and p-type impurities are sequentially ion-implanted into the upper surface of the p-type base region 3 to form the n⁺-type source region 4 and the p⁺-type contact region 8. A metal layer is formed on the n⁺-type source region 4, the p⁺-type contact region 8, and the insulating layer 15 by CVD, sputtering, or other methods. The metal layer is patterned to form the source electrode 22 and the gate pad 23. The back surface of the n⁺-type semiconductor layer 9x is ground until the n⁺-type semiconductor layer 9x reaches a predetermined thickness. As shown in FIG. 12B, the drain electrode 21 is formed on the back surface of the n⁺-type semiconductor layer 9x by CVD, sputtering, or other methods. Through the above steps, the semiconductor device 100 according to the embodiment is manufactured.

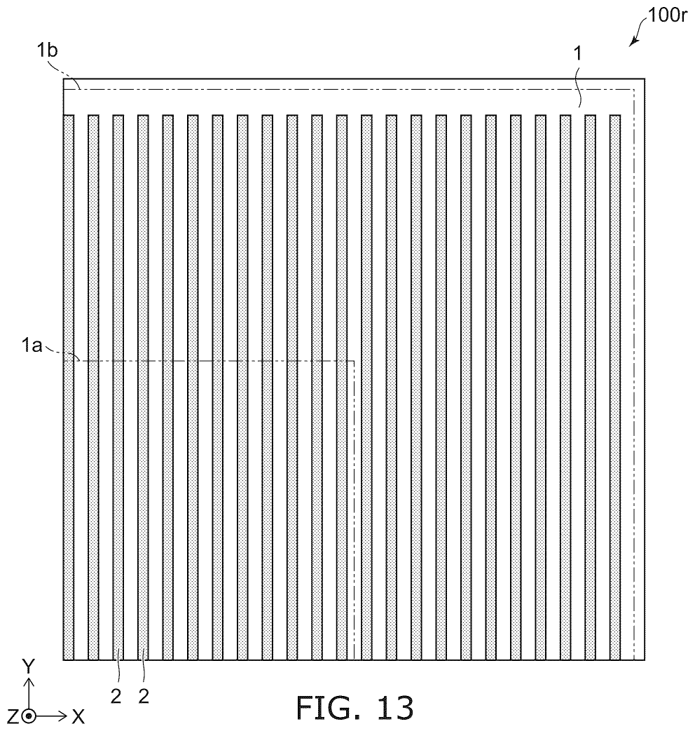

FIG. 13 is a plan view illustrating a portion of a semiconductor device according to a reference example.

In the semiconductor device 100r shown in FIG. 13, multiple p⁻-type pillar regions 2 are provided in the first portion 1a and the second portion 1b. The lengths of p⁻-type pillar regions 2 in the X-direction are the same as each other. The distances between adjacent p⁻-type pillar regions 2 in the X-direction are also the same as each other.

Advantages of the embodiment will now be described.

In the first portion 1a, the amount of p-type impurities in the p⁻-type pillar region 2 is preferably slightly greater than the amount of n-type impurities in the n⁻-type pillar region. In the first portion 1a, the electrical potential of the p⁻-type pillar region 2 is substantially the same as the electrical potential of the p-type base region 3. In the second portion 1b, the electrical potential of the p⁻-type pillar region 2 is easily propagated in the Y-direction where the pillar region is continuous, but is difficult to propagate in the X-direction. Therefore, when the amount of p-type impurities in the p⁻-type pillar region 2 in the first portion 1a is the same as the amount of n-type impurities in the n⁻-type pillar region, the spread of the depletion layer in the second portion 1b differs between the X-direction and the Y-direction. As a result, the breakdown voltage of the semiconductor device 100 may be reduced. In the first portion 1a, when the amount of p-type impurities in the p⁻-type pillar region 2 is slightly greater than the amount of n-type impurities in the n⁻-type pillar region, the depletion layer tends to spread in the X-direction as well in the second portion 1b. In the second portion 1b, the difference between the spread of the depletion layer along the X-direction and the spread of the depletion layer along the Y-direction can be reduced, and the breakdown voltage of the semiconductor device 100 can be improved.

On the other hand, when the semiconductor device 100 is turned off, the depletion layer spreads from the first portion 1a to the second portion 1b. During normal operation of the semiconductor device 100, it is desirable for the depletion layer not to reach the outermost p⁻-type pillar region. If the depletion layer reaches the outermost p⁻-type pillar region during normal operation, when a large voltage is temporarily applied to the semiconductor device 100, the depletion layer cannot spread further. In such a case, collision ionization may occur intensively at the outermost edge of the depletion layer, potentially leading to the destruction of the semiconductor device 100.

In the semiconductor device 100r, when the amount of p-type impurities in the p⁻-type pillar region 2 provided in the first portion 1a is greater than the amount of n-type impurities in the n⁻-type pillar region, even in the second portion 1b, the amount of p-type impurities in the p⁻-type pillar region 2 is greater than the amount of n-type impurities in the n⁻-type pillar region. In the second portion 1b, when the amount of p-type impurities in the p⁻-type pillar region 2 is greater than the amount of n-type impurities in the n⁻-type pillar region, the spread of the depletion layer in the second portion 1b is enhanced. In order to prevent the depletion layer from reaching the outermost p⁻-type pillar region, it is necessary to increase the size of the second portion 1b. As a result, the semiconductor device 100r becomes larger.

For this problem, in the semiconductor device 100 according to the embodiment, the p⁻-type pillar regions 5 and the p⁻-type pillar regions 6 are provided in the second portion 1b. As shown in FIG. 4, the distance D2x between adjacent p⁻-type pillar regions 5 is longer than the distance D1x between adjacent p⁻-type pillar regions 2. When the distance D2x is longer than the distance D1x, the amount of n-type impurities in the n⁻-type pillar region can be greater than the amount of p-type impurities in the p⁻-type pillar region 5. As a result, in the second portion 1b, the spread of the depletion layer along the X-direction can be suppressed.

Additionally, as shown in FIG. 4, the multiple p⁻-type pillar regions 2 and the multiple p⁻-type pillar regions 6 are provided in the X-direction and the Y-direction. In other words, n⁻-type pillar regions are provided between the p⁻-type pillar regions 2 and between the p⁻-type pillar regions 6 in the X-direction and the Y-direction. In such a case, the proportion of the n⁻-type pillar regions in the second portion 1b can be increased compared to a case where the p⁻-type pillar regions 2 continuously extend in the Y-direction, as in the semiconductor device 100r. As a result, even when the amount of p-type impurities in the p⁻-type pillar region 2 in the first portion 1a is greater than the amount of n-type impurities in the n⁻-type pillar region, the spread of the depletion layer along the Y-direction in the second portion 1b can be suppressed.

According to the embodiment, the spread of the depletion layer in the second portion 1b can be suppressed while reducing the difference in the spread of the depletion layer along the X-direction and the spread of the depletion layer along the Y-direction. As a result, the semiconductor device 100 can be downsized while maintaining the breakdown voltage of the semiconductor device 100.

The distance between the adjacent p⁻-type pillar regions 5 in the X-direction is preferably longer toward the outer periphery of the semiconductor device 100. According to this arrangement, the amount of n-type impurities in the n⁻-type pillar region can be increased toward the outer periphery of the semiconductor device 100. For example, compared to a case where the distance between the p⁻-type pillar regions 5 is made longer than the distance between the p⁻-type pillar regions 2 and the distances between the p⁻-type pillar regions 5 are made uniform, the spread of the depletion layer along the X-direction in the second portion 1b can be suppressed while suppressing the increase in electric field strength on the inner peripheral side of the second portion 1b.

The length L2x of the p⁻-type pillar region 5 in the X-direction may be different from the length L1x of the p⁻-type pillar region 2 in the X-direction. Preferably, as shown in FIG. 7A, the length L2x is the same as the length L1x. When the length L1x and length L2x are the same, the widths of the openings OP1 shown in FIG. 8 are also the same as each other. If the widths of the openings OP1 are different from each other, variation in the depths of the openings OP1 tends to increase. When the widths of the openings OP1 are the same, the variation in the depths of the openings OP1 can be suppressed. As a result, the amount of n-type impurities in the n⁻-type pillar region, the amount of p-type impurities in the p⁻-type pillar region 2, and the amount of p-type impurities in the p⁻-type pillar region 5 can be easily controlled. The variation in the spread of the depletion layer in the second portion 1b can be suppressed, and the reliability of the semiconductor device 100 can be improved. In addition, the manufacturing yield of the semiconductor device 100 can be improved.

The length of each p⁻-type pillar region 6 in the Y-direction is preferably shorter toward the outer periphery of the semiconductor device 100. According to this arrangement, the proportion of the number of n⁻-type pillar regions can be increased toward the outer periphery of the semiconductor device 100. For example, compared to a case where the lengths of the p⁻-type pillar regions 6 in the Y-direction are uniform, the increase in the electric field strength on the inner peripheral side of the second portion 1b can be suppressed, while suppressing the spread of the depletion layer along the Y-direction in the second portion 1b.

The distances in the Y-direction between adjacent p⁻-type pillar regions 6 are preferably the same. For example, as shown in FIG. 7B, the distance D1y between the p⁻-type pillar region 6a and the p⁻-type pillar region 6b is the same as the distance D2y between the p⁻-type pillar region 6a and the p⁻-type pillar region 6c. The distance in the Y-direction between adjacent p⁻-type pillar regions 6 depends on the width of the opening OP2 shown in FIG. 10. When the distance D1y and the distance D2y are the same, the widths of the openings OP2 are also the same as each other. When the widths of the openings OP2 are the same, variation in the depths of the openings OP2 can be suppressed. As a result, the amount of n-type impurities in the n⁻-type pillar region and the amount of p-type impurities in the p⁻-type pillar region 6 can be easily controlled. The variation in the spread of the depletion layer in the second portion 1b can be suppressed, and the reliability of the semiconductor device 100 can be improved. In addition, the manufacturing yield of the semiconductor device 100 can be improved.

In addition, as shown in FIG. 7B, the distance D3x in the X-direction between adjacent p⁻-type pillar regions 6 is preferably the same as the distance D1x in the X-direction between adjacent p⁻-type pillar regions 2. When the distance D3x and the distance D1x are the same, the p⁻-type pillar region 2 and the p⁻-type pillar region 6 can be formed by a common opening OP1. Thereby, the semiconductor device 100 can be easily manufactured, and the manufacturing yield of the semiconductor device 100 can be improved.

### First Modification

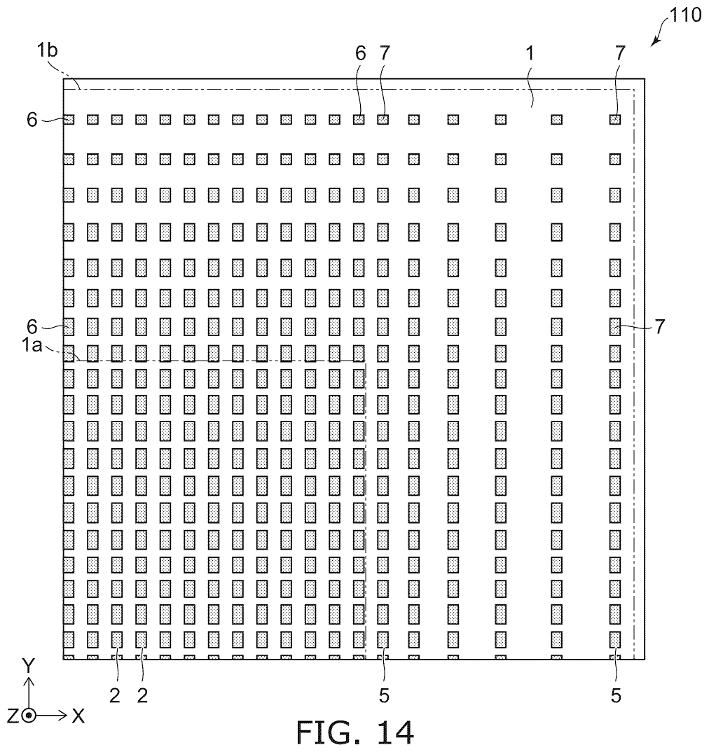

FIG. 14 is a plan view illustrating a portion of a semiconductor device according to a first modification of the embodiment.

In a semiconductor device 110 shown in FIG. 14, the distance in the Y-direction between adjacent p⁻-type pillar regions 6 is longer toward the outer periphery of the semiconductor device 110. As the distance between the p⁻-type pillar regions 6 becomes longer, the amount of n-type impurities in the n⁻-type pillar region increases toward the outer periphery of the semiconductor device 110. The length of each p⁻-type pillar region 6 in the Y-direction becomes shorter toward the outer periphery of the semiconductor device 110. Alternatively, the length of each p⁻-type pillar region 6 in the Y-direction may be the same. According to the semiconductor device 110, similarly to the semiconductor device 100, the spread of the depletion layer along the Y-direction in the second portion 1b can be suppressed.

However, if the distances between adjacent p⁻-type pillar regions 6 are different, it becomes necessary to make the widths of the openings OP2 shown in FIG. 10 different from each other. In such a case, the variation in the depths of the openings OP2 may increase. The difference between the amount of n-type impurities in the n⁻-type pillar region and the amount of p-type impurities in the p⁻-type pillar region 6 tends to increase, and the variation in the spread of the depletion layer in the second portion 1b tends to increase. Therefore, from the perspective of reliability, it is preferable for the distances between adjacent p⁻-type pillar regions 6 to be the same as each other.

### Second Modification

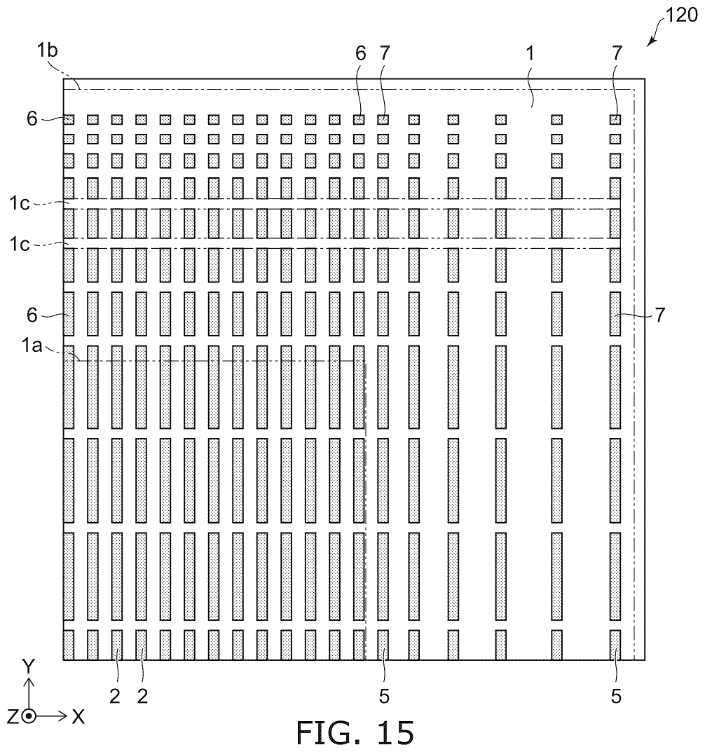

FIG. 15 is a plan view illustrating a portion of a semiconductor device according to a second modification of the embodiment.

In a semiconductor device 120 shown in FIG. 15, the first portion 1a and the second portion 1b both include an extending portion 1c. In the first portion 1a, the extending portion 1c extends along the X-direction between adjacent p⁻-type pillar regions 2 in the Y-direction. In the second portion 1b, the extending portion 1c extends along the X-direction between adjacent p⁻-type pillar regions 6 in the Y-direction. The n-type impurity concentration in the extending portion 1c is different from the n-type impurity concentration in other portions of the first portion 1a, and is different from the n-type impurity concentration in other portions of the second portion 1b. For example, the n-type impurity concentration in the extending portion 1c is greater than the n-type impurity concentration in other portions of the first portion 1a, and greater than the n-type impurity concentration in other portions of the second portion 1b. In the first portion 1a, the on-resistance of the semiconductor device 120 can be reduced by providing the extending portion 1c having a greater n-type impurity concentration. In addition, by providing the extending portion 1c in the second portion 1b, the spread of the depletion layer along the Y-direction can be suppressed. The difference between the spread of the depletion layer along the X-direction and the spread of the depletion layer along the Y-direction can be reduced, and the breakdown voltage of the semiconductor device 120 can be further improved.

The extending portion 1c corresponds to the n⁻-type semiconductor layer 1y filled in the opening OP2 in the step shown in FIG. 11. By adjusting the n-type impurity concentration in the n⁻-type semiconductor layer 1y, the n-type impurity concentration in the extending portion 1c can be controlled.

Embodiments of the present invention include the following features.

### Feature 1

A semiconductor device comprising:
a first electrode;
a first semiconductor region of a first conductivity type provided on the first electrode, the first semiconductor region including
   a first portion, and
   a second portion provided around the first portion in a first plane that is perpendicular to a first direction from the first electrode toward the first semiconductor region;
a plurality of second semiconductor regions of a second conductivity type provided in the first portion, the plurality of second semiconductor regions being separated from each other in a second direction and a third direction, the second direction being perpendicular to the first direction, the third direction being perpendicular to the first direction and the second direction;
a third semiconductor region of the second conductivity type provided on a portion of the plurality of second semiconductor regions arranged in the third direction, an impurity concentration of the second conductivity type in the third semiconductor region being greater than impurity concentrations of the second conductivity type in the portion of the plurality of second semiconductor regions;
a fourth semiconductor region of the first conductivity type provided on the third semiconductor region;
a gate electrode facing the third semiconductor region via a gate insulating layer;
a plurality of fifth semiconductor regions of the second conductivity type provided in the second portion, arranged with the plurality of second semiconductor regions in the second direction, and separated from each other in the second direction, a distance between two of the plurality of fifth semiconductor regions adjacent to each other being longer than a distance between two of the plurality of second semiconductor regions adjacent to each other;
a plurality of sixth semiconductor regions of the second conductivity type provided in the second portion, arranged with the plurality of second semiconductor regions in the third direction, and separated from each other in the second direction and the third direction;
a second electrode provided on the third semiconductor region and the fourth semiconductor region.

### Feature 2

The semiconductor device according to feature 1, wherein
a distance between adjacent fifth semiconductor regions in the second direction becomes longer toward an outer periphery of the semiconductor device.

### Feature 3

The semiconductor device according to feature 1 or 2, wherein:
one of the plurality of fifth semiconductor regions is adjacent, in the second direction, to another one of the plurality of fifth semiconductor regions and yet another one of the plurality of fifth semiconductor regions, and is positioned therebetween,
the other one of the plurality of fifth semiconductor regions is positioned, in the second direction, between one of the plurality of second semiconductor regions and the one of the plurality of fifth semiconductor regions, and
a distance between the one of the plurality of fifth semiconductor regions and the yet other one of the plurality of fifth semiconductor regions is longer than a distance between the one of the plurality of fifth semiconductor regions and the other one of the plurality of fifth semiconductor regions.

### Feature 4

The semiconductor device according to any one of features 1 to 3, wherein
a length in the second direction of one of the plurality of fifth semiconductor regions is the same as a length in the second direction of one of the plurality of second semiconductor regions.

### Feature 5

The semiconductor device according to any one of features 1 to 4, wherein
lengths in the third direction of the plurality of sixth semiconductor regions decrease toward an outer periphery of the semiconductor device.

### Feature 6

The semiconductor device according to any one of features 1 to 5, wherein
one of the plurality of sixth semiconductor regions is positioned, in the third direction, between another one of the plurality of sixth semiconductor regions and yet another one of the plurality of sixth semiconductor regions,
the other one of the plurality of sixth semiconductor regions is positioned, in the third direction, between one of the plurality of second semiconductor regions and the one of the plurality of sixth semiconductor regions, and
a length in the third direction of the one of the plurality of sixth semiconductor regions is shorter than a length in the third direction of the other one of the plurality of sixth semiconductor regions and longer than a length in the third direction of the yet other one of the plurality of sixth semiconductor regions.

### Feature 7

The semiconductor device according to feature 6, wherein:
in the third direction, the one of the plurality of sixth semiconductor regions is adjacent to the other one of the plurality of sixth semiconductor regions and the yet other one of the plurality of sixth semiconductor regions, and
a distance between the one of the plurality of sixth semiconductor regions and the other one of the plurality of sixth semiconductor regions is the same as a distance between the one of the plurality of sixth semiconductor regions and the yet other one of the plurality of sixth semiconductor regions.

### Feature 8

The semiconductor device according to any one of features 1 to 7, wherein
a distance between two of the plurality of sixth semiconductor regions adjacent to each other in the second direction is the same as a distance between two of the plurality of second semiconductor regions adjacent to each other in the second direction.

### Feature 9

The semiconductor device according to any one of features 1 to 8, further comprising a plurality of seventh semiconductor regions of the second conductivity type provided in the second portion,
the plurality of seventh semiconductor regions being arranged with the plurality of fifth semiconductor regions in the third direction and arranged with the plurality of sixth semiconductor regions in the second direction, and
the plurality of seventh semiconductor regions being separated from each other in the second direction and the third direction.

In the embodiments above, the relative levels of the impurity concentrations between the semiconductor regions can be confirmed using, for example, a scanning capacitance microscope (SCM). The carrier concentration in each semiconductor region can be considered to be equal to the activated impurity concentration in each semiconductor region. Accordingly, the relative levels of the carrier concentrations between the semiconductor regions also can be confirmed using SCM. The impurity concentration in each semiconductor region can be measured, for example, using secondary ion mass spectrometry (SIMS).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A semiconductor device comprising:
a first electrode;
a first semiconductor region of a first conductivity type provided on the first electrode, the first semiconductor region including
a first portion, and
a second portion provided around the first portion in a first plane that is perpendicular to a first direction from the first electrode toward the first semiconductor region;
a plurality of second semiconductor regions of a second conductivity type provided in the first portion, the plurality of second semiconductor regions being separated from each other in a second direction and a third direction, the second direction being perpendicular to the first direction, the third direction being perpendicular to the first direction and the second direction;
a third semiconductor region of the second conductivity type provided on a portion of the plurality of second semiconductor regions arranged in the third direction, an impurity concentration of the second conductivity type in the third semiconductor region being greater than impurity concentrations of the second conductivity type in the portion of the plurality of second semiconductor regions;
a fourth semiconductor region of the first conductivity type provided on the third semiconductor region;
a gate electrode facing the third semiconductor region via a gate insulating layer;
a plurality of fifth semiconductor regions of the second conductivity type provided in the second portion, arranged with the plurality of second semiconductor regions in the second direction, and separated from each other in the second direction, a distance between two of the plurality of fifth semiconductor regions adjacent to each other being longer than a distance between two of the plurality of second semiconductor regions adjacent to each other;
a plurality of sixth semiconductor regions of the second conductivity type provided in the second portion, arranged with the plurality of second semiconductor regions in the third direction, and separated from each other in the second direction and the third direction;
a second electrode provided on the third semiconductor region and the fourth semiconductor region.

2. The semiconductor device according to claim 1, wherein
a distance between adjacent fifth semiconductor regions in the second direction becomes longer toward an outer periphery of the semiconductor device.

3. The semiconductor device according to claim 1, wherein:
one of the plurality of fifth semiconductor regions is adjacent, in the second direction, to another one of the plurality of fifth semiconductor regions and yet another one of the plurality of fifth semiconductor regions, and is positioned therebetween,
the other one of the plurality of fifth semiconductor regions is positioned, in the second direction, between one of the plurality of second semiconductor regions and the one of the plurality of fifth semiconductor regions, and
a distance between the one of the plurality of fifth semiconductor regions and the yet other one of the plurality of fifth semiconductor regions is longer than a distance between the one of the plurality of fifth semiconductor regions and the other one of the plurality of fifth semiconductor regions.

4. The semiconductor device according to claim 3, wherein
a length in the second direction of the one of the plurality of fifth semiconductor regions, a length in the second direction of the other one of the plurality of fifth semiconductor regions, and a length in the second direction of the yet other one of the plurality of fifth semiconductor regions are the same.

5. The semiconductor device according to claim 1, wherein
a length in the second direction of one of the plurality of fifth semiconductor regions is the same as a length in the second direction of one of the plurality of second semiconductor regions.

6. The semiconductor device according to claim 5, wherein
a length in the third direction of the one of the plurality of fifth semiconductor regions is the same as a length in the third direction of the one of the plurality of second semiconductor regions.

7. The semiconductor device according to claim 1, wherein
lengths in the third direction of the plurality of sixth semiconductor regions decrease toward an outer periphery of the semiconductor device.

8. The semiconductor device according to claim 1, wherein
one of the plurality of sixth semiconductor regions is positioned, in the third direction, between another one of the plurality of sixth semiconductor regions and yet another one of the plurality of sixth semiconductor regions,
the other one of the plurality of sixth semiconductor regions is positioned, in the third direction, between one of the plurality of second semiconductor regions and the one of the plurality of sixth semiconductor regions, and
a length in the third direction of the one of the plurality of sixth semiconductor regions is shorter than a length in the third direction of the other one of the plurality of sixth semiconductor regions and longer than a length in the third direction of the yet other one of the plurality of sixth semiconductor regions.

9. The semiconductor device according to claim 8, wherein
a length in the second direction of the one of the plurality of sixth semiconductor regions, a length in the second direction of the other one of the plurality of sixth semiconductor regions, and a length in the second direction of the yet other one of the plurality of sixth semiconductor regions are the same.

10. The semiconductor device according to claim 8, wherein:
in the third direction, the one of the plurality of sixth semiconductor regions is adjacent to the other one of the plurality of sixth semiconductor regions and the yet other one of the plurality of sixth semiconductor regions, and
a distance between the one of the plurality of sixth semiconductor regions and the other one of the plurality of sixth semiconductor regions is the same as a distance between the one of the plurality of sixth semiconductor regions and the yet other one of the plurality of sixth semiconductor regions.

11. The semiconductor device according to claim 1, wherein
a distance between two of the plurality of sixth semiconductor regions adjacent to each other in the second direction is the same as a distance between two of the plurality of second semiconductor regions adjacent to each other in the second direction.

12. The semiconductor device according to claim 11, wherein
lengths in the second direction of the two of the plurality of second semiconductor regions and lengths in the second direction of two of the plurality of sixth semiconductor regions are the same.

13. The semiconductor device according to claim 1, further comprising a plurality of seventh semiconductor regions of the second conductivity type provided in the second portion,
the plurality of seventh semiconductor regions being arranged with the plurality of fifth semiconductor regions in the third direction and arranged with the plurality of sixth semiconductor regions in the second direction, and
the plurality of seventh semiconductor regions being separated from each other in the second direction and the third direction.

14. The semiconductor device according to claim 13, wherein
a length in the second direction of one of the plurality of seventh semiconductor regions is the same as a length in the second direction of one of the plurality of fifth semiconductor regions.

15. The semiconductor device according to claim 13, wherein
a distance between adjacent seventh semiconductor regions in the second direction becomes longer toward an outer periphery of the semiconductor device.

16. The semiconductor device according to claim 13, wherein
one of the plurality of seventh semiconductor regions is adjacent, in the second direction, to another one of the plurality of seventh semiconductor regions and yet another one of the plurality of seventh semiconductor regions, and is positioned therebetween,
the other one of the plurality of seventh semiconductor regions is positioned, in the second direction, between one of the plurality of sixth semiconductor regions and the one of the plurality of seventh semiconductor regions, and
a distance between the one of the plurality of seventh semiconductor regions and the yet other one of the plurality of seventh semiconductor regions is longer than a distance between the one of the plurality of seventh semiconductor regions and the other one of the plurality of seventh semiconductor regions.

17. The semiconductor device according to claim 16, wherein
a length in the second direction of the one of the plurality of seventh semiconductor regions, a length in the second direction of the other one of the plurality of seventh semiconductor regions, and a length in the second direction of the yet other one of the plurality of seventh semiconductor regions are the same.

18. The semiconductor device according to claim 13, wherein
lengths in the third direction of the plurality of seventh semiconductor regions decrease toward an outer periphery of the semiconductor device.

19. The semiconductor device according to claim 13, wherein
one of the plurality of seventh semiconductor regions is positioned, in the third direction, between another one of the plurality of seventh semiconductor regions and yet another one of the plurality of seventh semiconductor regions,
the other one of the plurality of seventh semiconductor regions is positioned, in the third direction, between one of the plurality of fifth semiconductor regions and the one of the plurality of seventh semiconductor regions, and
a length in the third direction of the one of the plurality of seventh semiconductor regions is shorter than a length in the third direction of the other one of the plurality of seventh semiconductor regions and longer than a length in the third direction of the yet other one of the plurality of seventh semiconductor regions.

20. The semiconductor device according to claim 19, wherein
in the third direction, the one of the plurality of seventh semiconductor regions is adjacent to the other one of the plurality of seventh semiconductor regions and the yet other one of the plurality of seventh semiconductor regions, and
a distance between the one of the plurality of seventh semiconductor regions and the other one of the plurality of seventh semiconductor regions is the same as a distance between the one of the plurality of seventh semiconductor regions and the yet other one of the plurality of seventh semiconductor regions.
